(19) United States
(12) Patent Application Publication
(10) Pub. No.: US 2005/0263076 A1
(43) Pub. Date: Dec. 1, 2005

(54) Atomic layer deposition apparatus having improved reactor and sample holder

(75) Inventors: Ran-ju Jung, Gyeonggi-do (KR); Yeon-taek Ryu, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 10/983,684

(22) Filed: Nov. 9, 2004

(30) Foreign Application Priority Data
May 28, 2004 (KR) 2004-38205

(51) Int. Cl. C23C 16/00

(52) U.S. Cl. 118/728

(57) ABSTRACT

Provided is an atomic layer deposition (ALD) apparatus that has an improved reactor and sample holder. The apparatus includes a reactor including an upper plate and a lower plate and accommodating a reaction chamber; and a sample holder supporting a sample loaded into the reaction chamber. The upper plate includes a bottom having a predetermined depth and a sidewall surrounding the bottom, and the bottom and the sidewall of the upper plate define the reaction chamber. At least one gas inlet and at least one gas outlet are installed at the sidewall of the upper plate. The sample holder includes a body and a cylindrical support member. The body has a support plate and a cylindrical support skirt. The sample is mounted on one side of the support plate and the support skirt extends from the other side of the support plate. Also, the support member is inserted in the body and supports the sample. The support plate includes a window that exposes the surface of the sample on which a thin layer is grown.

### BACKGROUND OF THE INVENTION

This application claims the priority of Korean Patent Application No. 2004-38205, filed on May 28, 2004 in the Korean Intellectual Property Office, the disclosure of which is incorporated herein in its entirety by reference.

1. Field of the Invention

The present invention relates to an atomic layer deposition (ALD) apparatus, and more particularly, to an ALD apparatus that has an improved reactor and sample holder so as to deposit uniform atomic layers.

2. Description of the Related Art

Atomic layer deposition (ALD) is one of the most important thin film growing techniques required for semiconductor manufacturing processes. In the ALD, while a source gas and a reactive gas are alternately injected into a reactor, gas absorption, surface reaction, and gas desorption are repetitively performed on the surface of a sample, thus depositing an atomic layer on the surface of the sample.

FIG. 1 is a cross-sectional view of a conventional ALD apparatus. A gas is continuously injected into a reactor 2 via a gas inlet 4, and most of the remaining gas, which is not used for depositing an atomic layer on a sample 8, is exhausted via a gas outlet 6. On the surface of the sample 8, the gas is absorbed, and a surface reaction is caused between the absorbed gas and a newly supplied gas.

As shown in FIG. 1, some of the gas injected into the reactor 2, which flows below a sample holder 10 or generates whirls around the sample 8, does not get used for the deposition of an atomic layer. Thus, the conventional ALD apparatus having the above-described structure wastes a large amount of gas.

Also, because of the arrangement of the sample holder 10 and the sample 8 in the conventional ALD apparatus, the gas whirls inside the reactor 2, precluding an efficient purge process.

If the gas whirls, the gas remains inside the reactor 2 during a purge process. Thus, when a reactive gas is injected into the reactor 2, the reactive gas reacts not with elements absorbed on the sample 8 but with the remaining source gas to form a cluster. This adversely affects the uniformity of a resulting atomic layer.

Further, in the conventional ALD apparatus, laminar gas flow is not achieved due to gas whirling in the reactor 2, so the gas is not uniformly distributed in the reactor 2.

Since the gas is not uniformly distributed in the reactor 2, it is difficult to uniformly deposit a thin layer. Accordingly, to deposit a uniform thin layer, the gas flowing over the sample 8 should form a laminar flow, and the reactive gas should flow uniformly over the sample 8.

FIG. 2 is a perspective view of the sample holder 10 shown in FIG. 1. The sample 8 is fixed to a top surface of the sample holder 10 using sample fixing screws 9.

Each of the sample fixing screws 9 includes a protrusion, which causes a gas to whirl inside the reactor 2 and thereby impede laminar flow of the gas as described above.

In a popular ALD apparatus, which was developed for in-situ analysis, a thin layer sample must be transferred in a vacuum for analysis. For this operation, a sample holder has a circular shape having a diameter of about 1 inch.

Because an ALD apparatus for in-situ analysis is very small in size as compared with other commonly used apparatuses, whirling and non-uniform distribution of gases in the reactor adversely affect an ALD process more seriously.

As described above, the conventional ALD apparatus wastes a large amount of gas and causes the gas to whirl in the reactor due to structural problems. This precludes an efficient purge process and laminar gas flow. As a result, the gas is not uniformly distributed in the reactor and thus, a uniform thin layer cannot be obtained.

Therefore, a new ALD apparatus is required to prevent waste of gas, minimize gas whirls, improve a purge process, induce laminar gas flow, and uniformly distribute the gas.

Above all, a reactor and a sample holder should be structurally improved.

### SUMMARY OF THE INVENTION

The present invention provides an atomic layer deposition (ALD) apparatus having an improved reactor, which reduces the amount of gas wasted, minimizes gas whirls in the reactor, and leads to uniform gas distribution.

The present invention also provides an ALD apparatus having an improved sample holder, which minimizes gas whirls in the reactor and induces laminar gas flow.

According to an aspect of the present invention, there is provided an atomic layer deposition apparatus comprising a reactor including an upper plate and a lower plate and accommodating a reaction chamber; and a sample holder supporting a sample loaded into the reaction chamber.

The upper plate includes a bottom having a predetermined depth and a sidewall surrounding the bottom, and the bottom and the sidewall define the reaction chamber. At least one gas inlet is installed at one side of the sidewall and allows a gas to flow into the reaction chamber, and at least one gas outlet is installed at the other side of the sidewall and allows a gas to flow out of the reaction chamber.

According to another aspect of the present invention, there is provided an atomic layer deposition apparatus comprising a reactor including an upper plate and a lower plate and accommodating a reaction chamber; and a sample holder supporting a sample loaded in the reaction chamber.

The sample holder includes a body and a cylindrical support member. The body has a support plate and a cylindrical support skirt. The sample is mounted on an inner surface of the support plate, and a support skirt extends from the support plate. Also, the support member is inserted in the body and supports the sample.

The support plate includes a window exposing the surface of the sample on which a thin layer is grown.

### BRIEF DESCRIPTION OF THE DRAWINGS

The above features and advantages of the present invention will become more apparent by describing in detail exemplary embodiments thereof with reference to the attached drawings in which:

FIG. 1 is a cross-sectional view of a conventional atomic layer deposition (ALD) apparatus;

FIG. 2 is a perspective view of a sample holder shown in FIG. 1;

FIG. 3 is a cross-sectional view of an ALD apparatus having an improved reactor and sample holder according to an embodiment of the present invention;

FIG. 4 is an exploded perspective view of the reactor shown in FIG. 3;

FIGS. 5 and 6 are respectively a perspective view and plan view of a bottom surface of an upper plate of the reactor shown in FIG. 3;

FIGS. 7 and 8 are respectively a perspective view and plan view of a bottom surface of a reactor according to another embodiment of the present invention;

FIG. 9 is an exploded perspective view of the sample holder shown in FIG. 3;

FIG. 10 is a longitudinal sectional view of the sample holder shown in FIG. 3;

FIG. 11 is an exploded perspective view of a sample holder according to yet another embodiment of the present invention;

FIG. 12 is a longitudinal sectional view of the sample holder shown in FIG. 11;

FIGS. 13 through 15 are exploded perspective views of a sample holder according to further embodiments of the present invention; and

FIG. 16 is a cross-sectional view of an ALD apparatus according to another embodiment of the present invention.

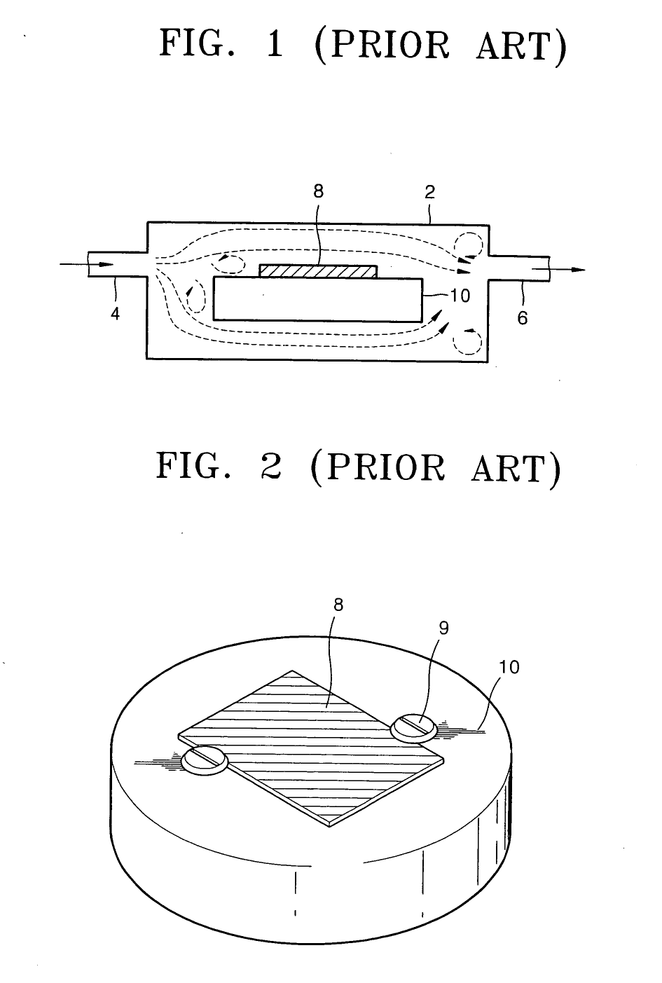

### DETAILED DESCRIPTION OF THE INVENTION

The present invention will now be described more fully with reference to the accompanying drawings, in which exemplary embodiments of the invention are shown.

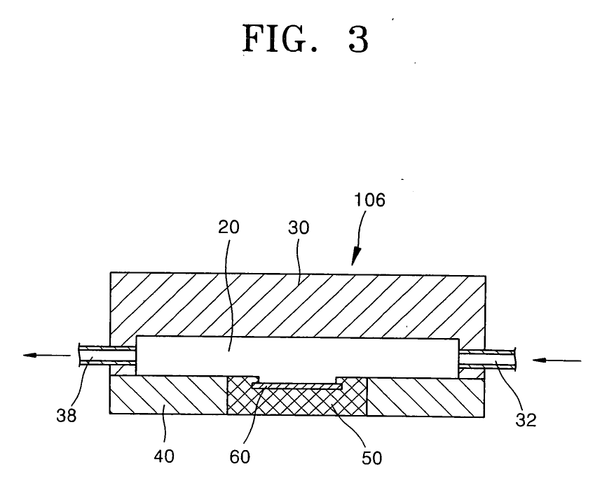

FIG. 3 is a cross-sectional view of an atomic layer deposition (ALD) apparatus having an improved reactor and sample holder according to an embodiment of the present invention.

The ALD apparatus includes a reactor 106 and a sample holder 50. The reactor 106 accommodates a reaction chamber 20, and the sample holder 50 supports a sample 60 loaded into the reaction chamber 20.

The reactor 106 includes an upper plate 30 and a lower plate 40, and the reaction chamber 20 is installed therebetween.

While a source gas and a reactive gas are alternately injected into the reaction chamber 20 through a gas supply pipe 32, gas absorption, surface reaction, and gas desorption are repetitively performed, thus depositing a thin layer on a monatomic scale on the surface of the sample 60. Then, the remaining gas, which is not used for deposition, is exhausted through a gas exhaust pipe 38.

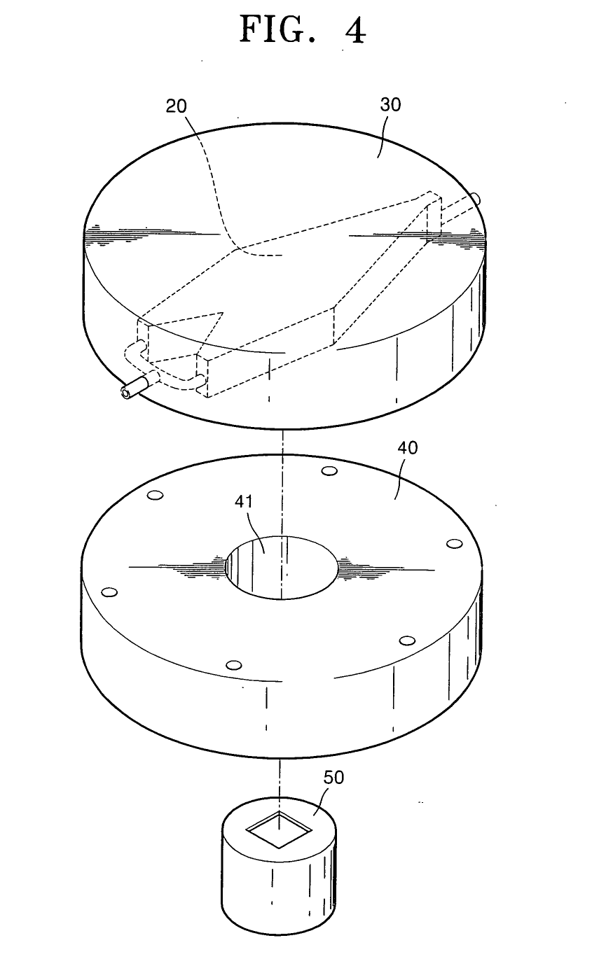

FIG. 4 is an exploded perspective view of the reactor 106 shown in FIG. 3.

Referring to FIG. 4, the reactor 106 includes the upper plate 30 and the lower plate 40, and the reaction chamber 20 where a layer that will be formed on the sample 60 is provided between the upper and lower plates 30 and 40. A holder door 41 is formed in the lower plate 40, and the sample holder 50 is loaded and unloaded via the holder door 41.

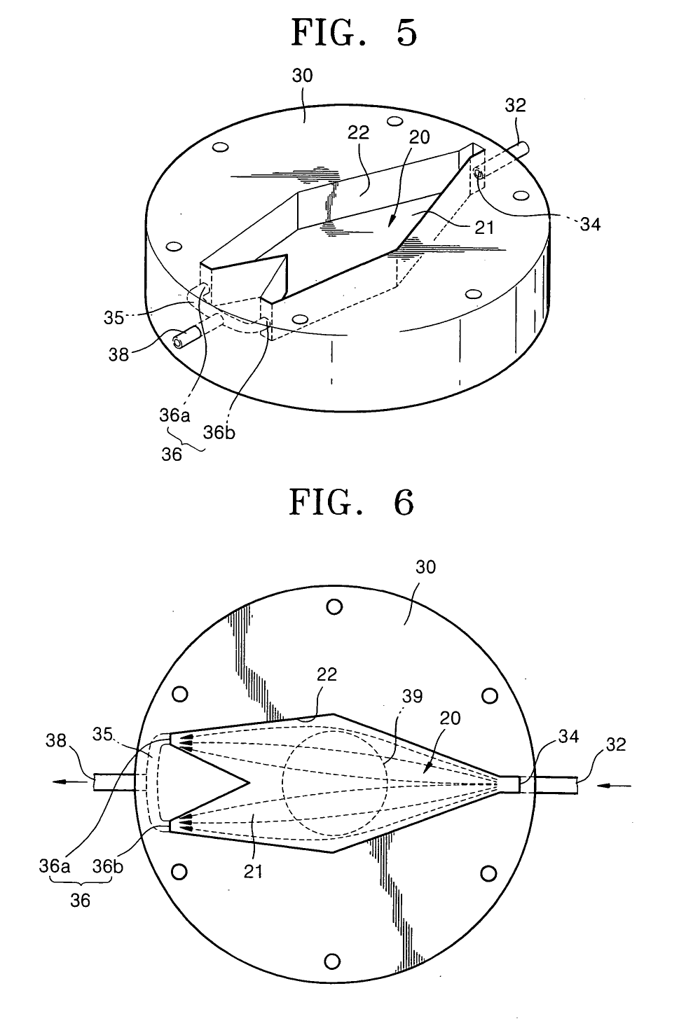

FIGS. 5 and 6 are respectively a perspective view and plan view of a bottom surface of the upper plate 30 of the reactor 106 shown in FIG. 3.

The reaction chamber 20 formed in the upper plate 30 includes a bottom 21 having a predetermined depth and a sidewall 22 surrounding the bottom 21. A gas inlet 34 is installed on one side of the sidewall 22 to allow a gas to flow into the reaction chamber 20, and a gas outlet 36 is installed on the other side of the sidewall 22 to allow the gas to flow out of the reaction chamber 20.

The gas outlet 36 includes two sub gas outlets 36a and 36b, which are connected to each other by a gas conflux pipe 35 installed inside the upper plate 30.

The gas inlet 34 is connected to the gas supply pipe 32, and the gas outlet 36 is connected to the gas exhaust pipe 38 by the gas conflux pipe 35.

The width of the reaction chamber 20 installed in the upper plate 30 is greater in the center than near the gas inlet 34 and near the gas outlet 36.

Referring to FIG. 6, a region 39 as illustrated with a dotted circle in the center of the upper plate 30 refers to a space in the reaction chamber 20 facing the sample holder 50 disposed on the lower plate 40, and the width of the reaction chamber 20 formed in the upper plate 30 may be greater than the diameter of the sample holder 50.

By forming the reaction chamber 30 having the sidewall 22 and the bottom 21 to the smallest size possible, a space for allowing the gas to be whirled in the reaction chamber 20 can be minimized. In other words, the space for allowing gas whirls around the sample 60 can be eliminated, and the reaction chamber 20 can be formed to a small size required for gas flow, thus enabling deposition of a thin layer on the upper plate 30 due to minimal gas flow.

Accordingly, since the present invention can suppress gas whirls, a desired thin layer can be deposited, the amount of a reactive gas wasted can be reduced unlike in a conventional ALD apparatus, and reaction efficiency can be improved.

Referring to FIG. 6, as a gas is injected via the gas inlet 34 into the reaction chamber 20, the gas spreads and flows throughout the reaction chamber 20. After surface reaction is completed, the remaining gas is exhausted via the two sub gas outlets 36a and 36b.

In the reaction chamber 20 having this structure, the gas is uniformly distributed to generate a laminar flow and enable uniform deposition of an atomic layer.

Therefore, the ALD apparatus having the improved reactor 106 no longer wastes the gas during ALD and minimizes gas whirls inside the reactor 106.

Also, a purge process can be effectively performed in the reactor 106, and the gas can form a laminar flow so as to uniformly distribute the gas. Thus, an atomic layer can be uniformly deposited.

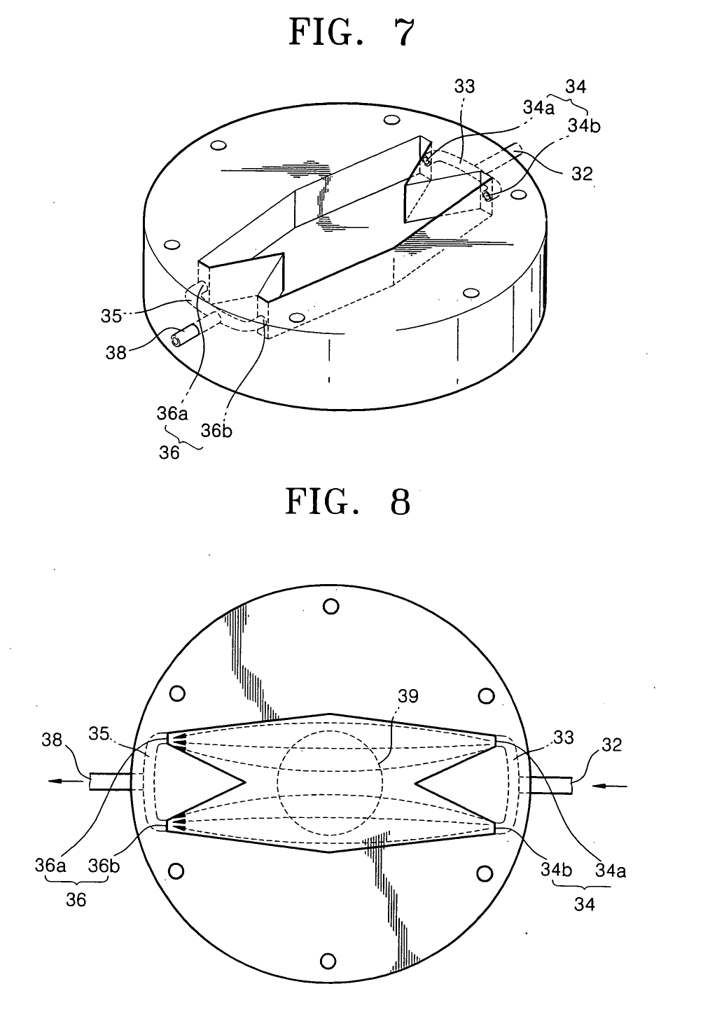

FIGS. 7 and 8 are a perspective view and plan view of a bottom of an upper plate of a reactor according to another embodiment of the present invention.

The reactor of the present embodiment is similar to the reactor 106 shown in FIG. 5 except that a gas inlet 34 includes two sub gas inlets 34a and 34b. The two sub gas inlets 34a and 34b are connected to a gas supply pipe 32 by a gas branch pipe 33.

Thus, when a gas is injected via the two sub gas inlets 34a and 34b into a reaction chamber 20, the gas uniformly flows throughout the reaction chamber 20 and forms a laminar flow in the reaction chamber 20. After surface reaction is completed, the remaining gas is exhausted via two sub gas outlets 36a and 36b.

In the embodiments of the present invention, the gas inlet includes one or two sub gas inlets. However, the present invention is not limited thereto, but the gas inlet may include two or more sub gas inlets.

Also, although the gas outlet includes two sub gas outlets in the embodiments of the present invention, the gas outlet may include only one sub gas outlet or two or more sub gas outlets.

These various changes may be easily made from the foregoing embodiments.

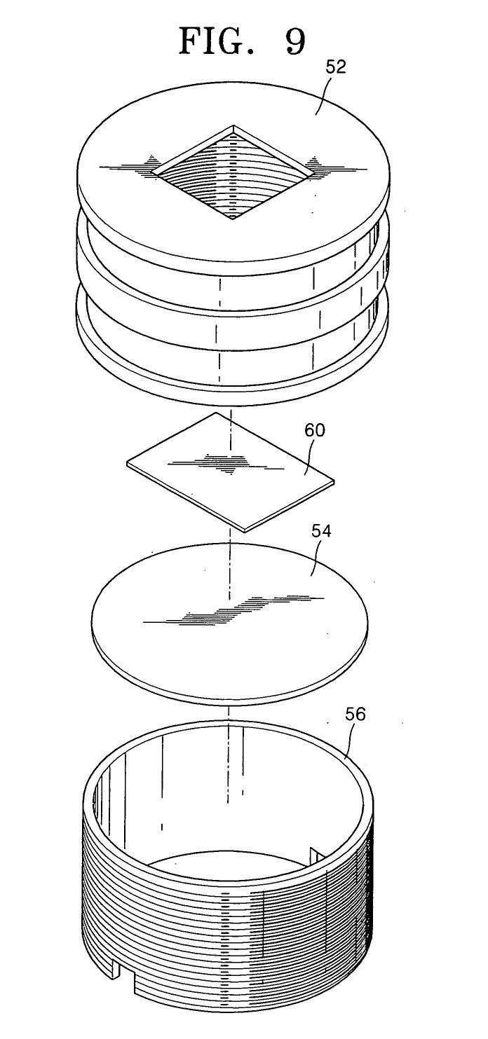

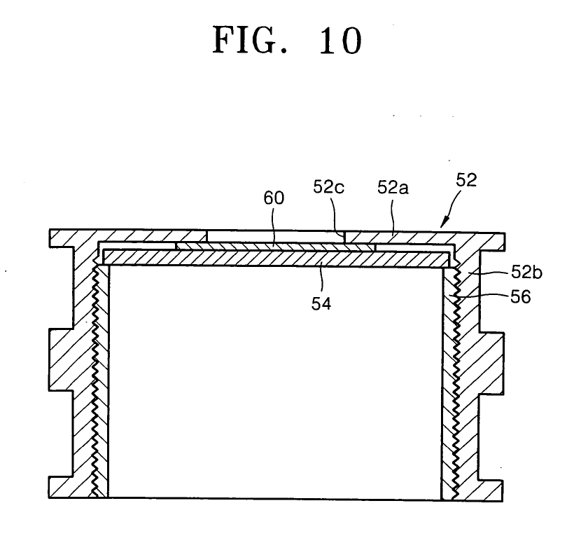

FIG. 9 is an exploded perspective view of the sample holder 50 shown in FIG. 3, and FIG. 10 is a longitudinal sectional view of the sample holder 50.

Referring to FIGS. 9 and 10, the sample holder 50 includes a body 52 and a cylindrical support member 56. The body 52 includes a window 52c formed in the top surface, and the support member 56 is inserted in the body 52 and supports the sample 60.

The body 52 includes a support plate 52a and a cylindrical support skirt 52b. The sample 60 is mounted on an inner surface of the support plate 52a, and the support skirt 52b extends from the support plate 52a. The support plate 52a includes the window 52c that exposes the surface of the sample 60 on which a thin layer is deposited, and the sample 60 is mounted on an inner surface of the support plate 52a.

The sample holder 50 may further include a pressing plate 54, which is inserted between the body 52 and the support member 56 and presses the sample 60 against the support plate 52a having the window 52c.

A sample transfer groove is formed in an outer circumferential surface of the body 52 of the sample holder 50, and a screw thread (not shown) is formed in an inner circumferential surface thereof to be combined with the support member 56. Also, another screw thread is formed in an outer circumferential surface of the support member 56 to be combined with the body 52.

Also, a sample heater (not shown) may be installed inside the support member 56 to directly heat the sample 60. In a bottom surface of the support member 56, a groove, in which is inserted a unit for rotating the support member 56 to combine the support member 56 with the body 52, may be formed.

The sample 60 is loaded into the body 52 and exposed to the reaction chamber 20 via the window 52c formed in the top surface of the body 52, during ALD.

The sample 60 is supported by the support member 56 inserted in the body 52. The sample 60 is inserted into the body 52, the pressing plate 54 is inserted into the body 52 to support the sample 60, and then the support member 56 is inserted into the body 52 so as to fix the sample 60 to the pressing plate 54.

A gas injected into the reactor 106 reacts with the sample 60 exposed via the window 52c formed in the top surface of the body 52 so that a thin layer is deposited on the monatomic scale. Since the sample 60 is loaded in the sample holder 50, gas whirls caused by a protrusion of the sample 60 can be prevented.

Unlike conventional ALD apparatuses, the above-described structure of the sample holder 50 does not include protrusions of sample fixing screws and a protrusion of a sample, which also cause gas whirls.

Also, gas whirls can be minimized in the reactor 106 during ALD, and factors that hinder the laminar flow of a gas can be minimized. Accordingly, the gas can be uniformly distributed in the reactor 106 to deposit a uniform atomic layer.

Since an empty sample holder 50 has reduced heat capacity, it is easy to heat the sample 60. It is possible to install the sample heater under the sample holder 50 to directly heat the sample 60 and control the temperature of the sample 60. Thus, the temperature of the sample 60 can be controlled using only a halogen lamp without an additional annealing apparatus.

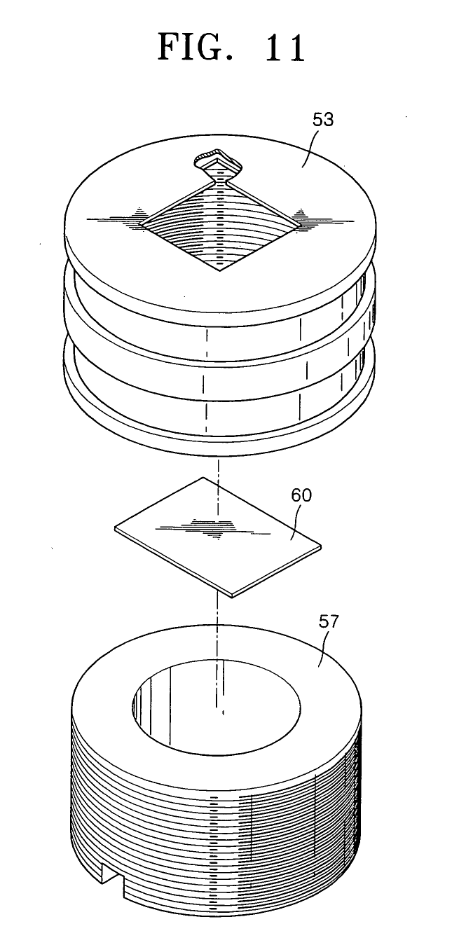

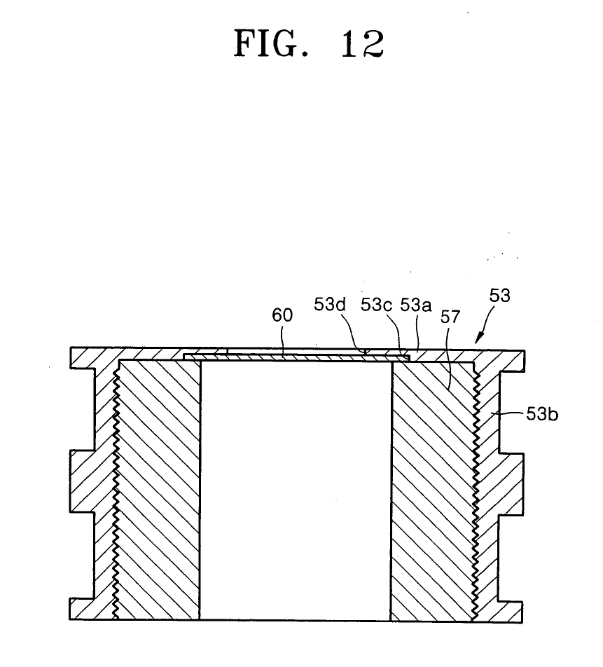

FIG. 11 is an exploded perspective view of a sample holder according to yet another embodiment of the present invention, and FIG. 12 is a longitudinal sectional view of the sample holder shown in FIG. 11.

A body 53 includes a support plate 53a and a cylindrical support skirt 53b. A sample 60 is mounted on an inner surface of the support plate 53a, and the cylindrical support skirt 53b extends from the support plate 53a. A sample mounting groove 53c for mounting the sample 60 is formed in an inner surface of the support plate 53a, and a window 53d via which one side of the sample 60 is exposed is formed in a bottom of the sample mounting groove 53c.

In the present embodiment, when the sample 60 is pushed into the sample mounting groove 53c, the sample 60 can be supported by only a support member 57 without the pressing plate 54 shown in FIG. 9.

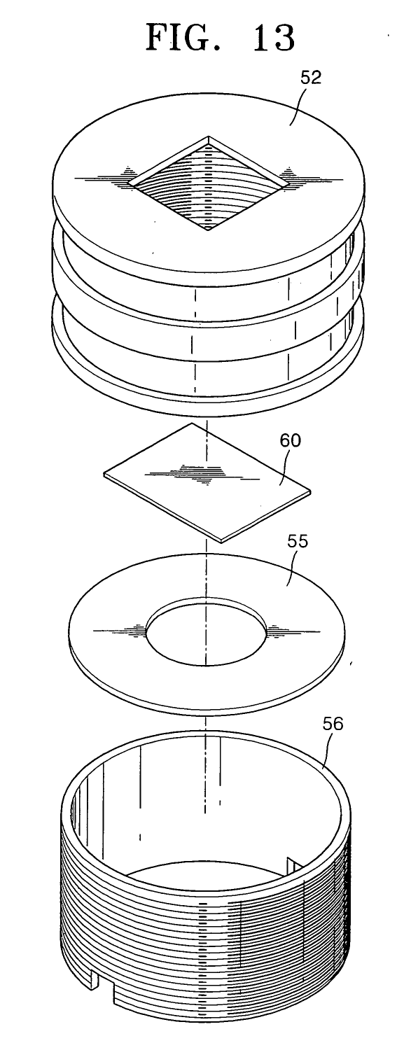

FIGS. 13 through 15 are exploded perspective views of sample holders according to further embodiments of the present invention.

Referring to FIG. 13, a pressing plate 55 includes an opening, via which a sample heater loaded through a bottom of a sample holder 50 can directly heat a sample 60. Accordingly, heat conductivity is enhanced so that the temperature of the sample 60 can be efficiently controlled.

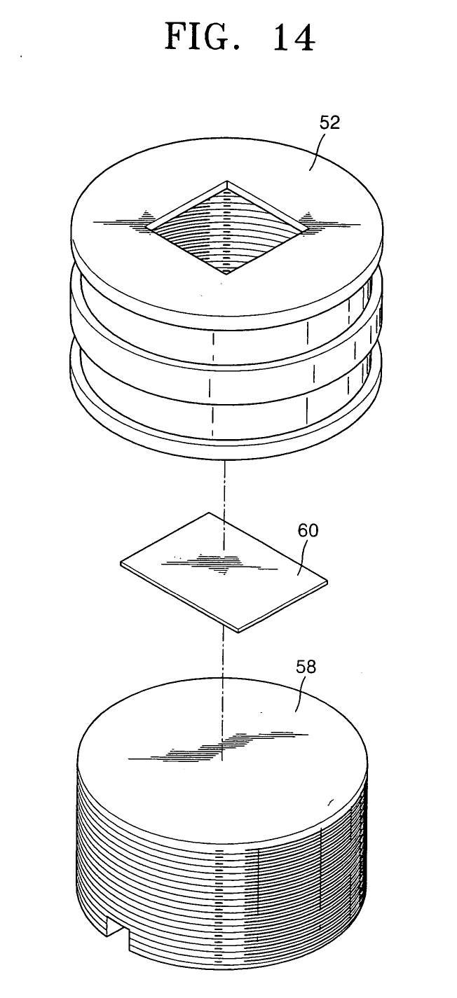

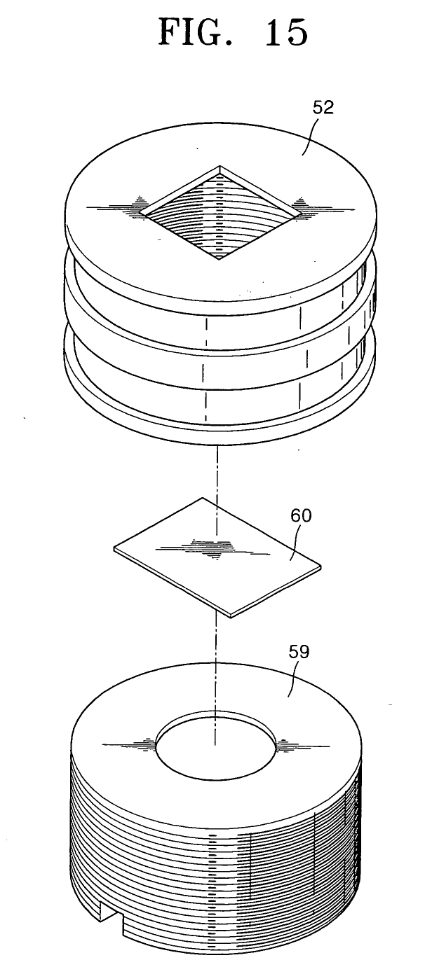

Referring to FIGS. 14 and 15, it can be seen that various changes in the sample holder 50 are possible.

The sample holder shown in FIG. 14 includes a support member 58, of which one side is covered, and can have the same effect as the sample holder 50 shown in FIG. 9, without using a pressing plate.

Also, in the sample holder shown in FIG. 15, one side of a support member 59 is covered, and an opening is formed in the support member 59. Thus, the sample holder can have the same effect as the sample holder 50 shown in FIG. 13.

These various changes of the sample holder can be easily made from the foregoing embodiments.

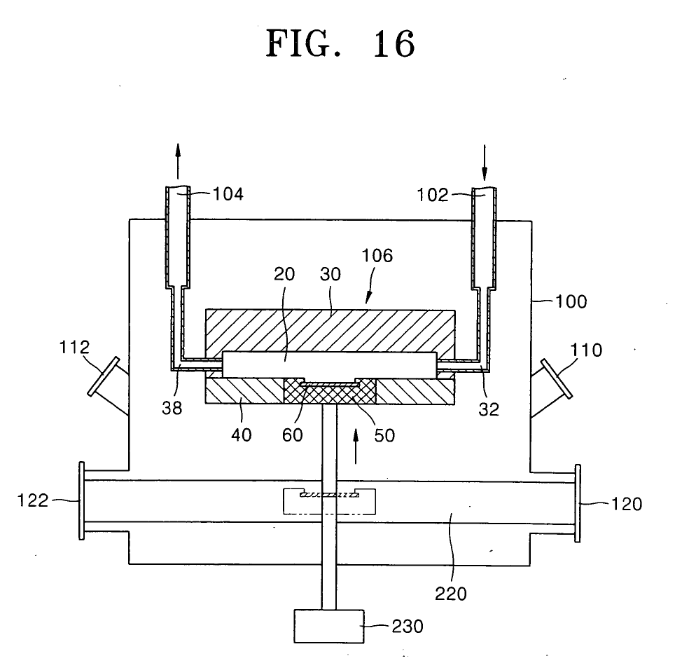

FIG. 16 is a cross-sectional view of an ALD apparatus according to another embodiment of the present invention.

The ALD apparatus shown in FIG. 3 may be installed in a vacuum container 100.

The vacuum container 100 may further include a sample transfer path 220, a first sample transfer port 120, a second sample transfer port 122, a first port 110, and a second port 112. The sample transfer path 220 allows the sample (60 of FIG. 3) to be transferred out of the vacuum container 100. The first and second sample transfer ports 120 and 122 are connected to the sample transfer path 220 and allow the sample 60 to be transferred to an electron spectroscope for chemical analysis (ESCA) (not shown), which is externally provided. The first and second ports 110 and 112 are used to further mount a spectroscopic ellipsometer (SE) (not shown) on the vacuum container 100.

The SE is mounted on the first and second ports 110 and 112 and allows polarized light to be incident on the sample 60 so that information on the sample 60 can be obtained from the reflected polarized light.

The ESCA is an apparatus for analyzing the energy of an optical electron emitted from the surface of the sample 60 when a specific X-ray is incident on the sample 60. Thus, by using the ESCA, the composition and chemical combination of a surface layer of the sample 60 can be extracted.

Also, the ALD apparatus may further include a sample position controller 230.

The sample position controller 230 moves the sample 60 to a position in the reaction chamber 20 which is appropriate for depositing a monatomic layer or moves the sample 60 toward the first and second ports 110 and 112, on which the SE is mounted, to measure the thickness and density of the sample 60.

As described above, the ALD apparatus having the foregoing vacuum container 100 may further include a different kind of analyzer outside the vacuum container 100. Thus, both deposition and analysis of a monatomic layer can be performed at the same time using the single ALD apparatus.

The ALD apparatus of the present invention reduces the amount of a gas wasted during ALD and minimizes gas whirls inside a reactor.

Also, a purge process can be effectively performed in the reactor, and laminar flow of the gas is achieved to enable uniform deposition. Accordingly, an atomic layer can be uniformly deposited.

Further, since an empty sample holder can have a reduced heat capacity, it is possible to control the temperature of a sample by directly heating the sample using only a halogen lamp appropriate for a sample holder without an additional annealing apparatus.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An atomic layer deposition apparatus comprising:
a reactor including an upper plate and a lower plate and accommodating a reaction chamber; and
a sample holder supporting a sample loaded into the reaction chamber,
wherein the upper plate includes a bottom having a predetermined depth and a sidewall surrounding the bottom, the bottom and the sidewall defining the reaction chamber, at least one gas inlet installed at one side of the sidewall and allowing a gas to flow into the reaction chamber, and at least one gas outlet installed at the other side of the sidewall and allowing a gas to flow out of the reaction chamber.

2. The apparatus of claim 1, wherein the width of the reaction chamber formed in the upper plate is greater in the center than near the gas inlet and near the gas outlet.

3. The apparatus of claim 1, wherein the lower plate includes a holder door via which the sample holder is loaded and unloaded.

4. The apparatus of claim 1, wherein the sample holder includes:
a body having a support plate and a cylindrical support skirt, wherein the sample is mounted on an inner surface of the support plate and the support skirt extends from the support plate; and
a cylindrical support member inserted in the body and supporting the sample,
wherein the support plate includes a window that exposes the surface of the sample on which a thin layer is grown.

5. The apparatus of claim 4, wherein the sample holder further includes a pressing plate inserted between the body and the support member and pressing the sample against the support plate including the window.

6. The apparatus of claim 4, wherein a sample mounting groove on which the sample is mounted is formed in an inner surface of the support plate,
and wherein the window for exposing one side of the sample is formed in a bottom of the sample mounting groove.

7. The apparatus of claim 1, further comprising a vacuum container installed to surround the reactor and the sample holder and maintained in vacuum.

8. The apparatus of claim 7, further comprising a port mounting a spectroscopic ellipsometry on the vacuum container.

9. The apparatus of claim 7, wherein the vacuum container further comprises:
a sample transfer path transferring the sample out of the vacuum container; and
a sample transfer port connected to the sample transfer path.

10. The apparatus of claim 9, wherein the sample transfer port is connected to an electron spectroscope for chemical analysis that is externally provided.

11. The apparatus of claim 1, further comprising a sample position controller transferring the sample to the reaction chamber.

12. An atomic layer deposition apparatus comprising:
a reactor including an upper plate and a lower plate and accommodating a reaction chamber; and
a sample holder supporting a sample loaded in the reaction chamber,
wherein the sample holder includes:
a body having a support plate and a cylindrical support port, wherein the sample is mounted on an inner surface of the support plate and a cylindrical support skirt extends from the support plate; and
a cylindrical support member inserted in the body and supporting the sample,
and wherein the support plate includes a window exposing the surface of the sample on which a thin layer is grown.

13. The apparatus of claim 12, wherein the lower plate includes a holder door via which the sample holder is loaded and unloaded.

14. The apparatus of claim 12, wherein the sample holder further includes a pressing plate inserted between the body and the support member and pressing the sample against the support plate including the window.

15. The apparatus of claim 12, wherein at least one groove is formed in a bottom of the support member.

16. The apparatus of claim 12, wherein a sample mounting groove on which the sample is mounted is formed in the inner surface of the support plate,
and the window for exposing one side of the sample is formed in the bottom of the sample mounting groove.

17. The apparatus of claim 12, further comprising a vacuum container installed to surround the reactor and the sample holder and maintained in vacuum.

18. The apparatus of claim 17, further comprising a port mounting a spectroscopic ellipsometer on the vacuum container.

19. The apparatus of claim 17, wherein the vacuum container further comprises:
a sample transfer path transferring the sample out of the vacuum container; and
a sample transfer port connected to the sample transfer path.

20. The apparatus of claim 19, wherein the sample transfer port is connected to an electron spectroscope for chemical analysis that is externally provided.

21. The apparatus of claim 12, further comprising a sample position controller transferring the sample to the reaction chamber.
